(19) United States
(12) Patent Application Publication
(10) Pub. No.: US 2001/0050582 A1
(43) Pub. Date: Dec. 13, 2001

(54) INPUT CIRCUIT HAVING CURRENT REGULATING TRANSISTOR

(76) Inventor: NAOHARU SHINOZAKI, KAWASAKI-SHI (JP)

Correspondence Address: ARENT FOX KINTNER PLOTKIN & KAHN PLLC, 1050 CONNECTICUT AVENUE, N.W., SUITE 600, WASHINGTON, DC, 20036-5339, US

(21) Appl. No.: 09/385,014

(22) Filed: Aug. 27, 1999

(30) Foreign Application Priority Data
Oct. 7, 1998 (JP) 10-285286

(51) Int. Cl. H03K 5/12

(52) U.S. Cl. 327/170

(57) ABSTRACT

An input circuit for an integrated circuit receives an external signal and generates an amplified internal signal which has substantially equal rise and fall signal timing. That is, the rise time of a signal generated by the input circuit is substantially the same as the fall time of signal. This effect is achieved by regulating the current flowing through the input circuit. The input circuit includes a differential circuit which includes a first transistor that receives the external signal at its gate and a second transistor that receives a reference voltage at its gate. Sources of the first and second transistors are connected in common, and the differential circuit generates an internal signal in accordance with the current flowing through the first and second transistors. A current regulating circuit is connected to the differential circuit and regulates the current flowing through the differential circuit in response to the internal signal.

### BACKGROUND OF THE INVENTION

The present invention relates to input circuits, and more particularly, to input circuits which amplify external signals to generate internal signals having predetermined amplitudes.

Recent increases in the speed of semiconductor memory devices have been followed by a decrease in the amplitude of external input signals. Accordingly, semiconductor memory devices are provided with input circuits which amplify external input signals to generate internal input signals having predetermined amplitudes. An input circuit generates internal input signals which rise and fall in response to the rising edges and falling edges of external input signals.

FIG. 1 is a circuit diagram showing a prior art input latch circuit 1. The input latch circuit 1 includes a first input circuit 2a, a second input circuit 2b, and a latch circuit 3. The first input circuit 2a receives an external data strobe signal DQS through an input pad 4a. The external data strobe signal DQS is a decreased amplitude signal that alternates between a first level V_{IH} and a second level V_{IL}, which are based on predetermined standards. The V_{IH} level is lower than the potential of a high potential power supply V_{CC} by a predetermined value, and the V_{IL} level is higher than the potential of a low potential power supply V_{SS} by a predetermined value.

The input circuit 2a amplifies the external data strobe signal DQS to generate a data strobe signal dqsz that alternates between the levels of the power supplies V_{CC}, V_{SS}. The phase of the data strobe signal dqsz is substantially the same as that of the external data strobe signal DQS. The data strobe signal dqsz is sent to the latch circuit 3.

As shown in FIG. 2, the input circuit 2a includes three NMOS transistors T_{N1}-T_{N3}, two PMOS transistors T_{P1},T_{P2}, and an inverter circuit 5. The sources of the NMOS transistors T_{N1}, T_{N2} are connected to each other at a connection node N1 and are further connected to a low potential power supply V_{SS} by way of the NMOS transistor T_{N3}. The gate of the NMOS transistor T_{N3} is connected to a high potential power supply V_{CC}. Accordingly, the NMOS transistor T_{N3} functions as a constant current source that keeps the potential at the node N1 constant.

The drain of the NMOS transistor T_{N1} is connected to a high potential power supply V_{CC} through the PMOS transistor T_{P1}. The drain of the NMOS transistor T_{N2} is connected to the high potential power supply V_{CC} through the PMOS transistor T_{P2}. The gates of the PMOS transistors T_{P1}, T_{P2} are connected to each other and to the drain of the PMOS transistor T_{P2}. Accordingly, the PMOS transistors T_{P1}, T_{P2} form a current mirror circuit 6.

The gate of the NMOS transistor T_{N1} is provided with the external data strobe signal DQS. The gate of the NMOS transistor T_{N2} is provided with a reference voltage V_{ref}. The reference voltage V_{ref} is the potential taken at the middle of the levels of the power supplies V_{CC}, V_{SS} ((V_{CC}+V_{SS})/2) and the potential taken at the middle of the V_{IH}, V_{IL} levels.

The drain of the NMOS transistor T_{N1} and the drain of the PMOS transistor T_{P1} are connected to each other at a node N2 (output node), which is connected to the input terminal of the inverter circuit 5. The inverter circuit 5 receives power from the power supplies V_{CC}, V_{SS} and generates the data strobe signal dqsz, which alternates between the levels of the power supplies V_{CC}, V_{SS}.

Referring to FIG. 3, when the external data strobe signal DQS is at the V_{IH} level, which is higher than the reference voltage V_{ref}, the current drive capacity of the NMOS, transistor T_{N1} is higher than that of the NMOS transistor T_{N2}. This increases the drain current of the NMOS transistor T_{N1} and decreases the drain current of the NMOS transistor T_{N2}. Thus, the current drive capacity of the current mirror circuit 6 decreases, and the drain current of the PMOS transistor T_{P1} decreases. Accordingly, the potential at the node N2 falls to substantially the low potential power supply V_{SS} level and the inverter circuit 5 outputs a data strobe signal dqsz having the high potential power supply V_{CC} level.

If the external data strobe signal DQS is at the V_{IL} level, which is lower than the reference voltage V_{ref}, the inverter circuit 5 outputs a data strobe signal dqsz having the low potential power supply V_{SS} level.

As shown in FIG. 1, the second input circuit 2b receives an external data signal DQ via an input pad 4b and generates a data signal dqz, which alternates between the power supply V_{CC}, V_{SS} levels and which phase is substantially the same as the external data signal DQ. The amplitude of the external data signal DQ is substantially the same as that of the external data strobe signal DQS. The data signal dqz is sent to the latch circuit 3.

The latch circuit 3 acquires and latches the data signal dqz in response to the rising edge of the data strobe signal dqsz and holds the latched signal until the subsequent rising of the data strobe signal dqsz. The latch circuit 3 sends the latched signal as an internal data signal dinz to an internal circuit (not shown).

Accordingly, as shown in FIG. 4, the input latch circuit 1 acquires and latches the external data signal DQ in response to the rising edge of the external data strobe signal DQS and holds the latched signal as the internal data signal dinz until the subsequent rising of the external data strobe signal DQS. The timing of the external data signal DQ and the external data strobe signal DQS are set such that the edges of the external data strobe signal DQS are located halfway between those of the external data signal DQ. In other words, as shown in FIG. 4, the timing of the signals is determined such that the setup time tIS and the hold time tIH of the external data signal DQ are substantially equal to each other.

The current drive capability of the NMOS transistor T_{N1}, the gate of which is provided with the external data strobe DQS having a V_{IH} level, is greater than that of the NMOS transistor T_{N2}, the gate of which is provided with the reference voltage V_{ref}. In other words, the drain current of the NMOS transistor T_{N2} (i.e., the current provided to the node N2 of the current mirror circuit 6 in correspondence with the drain current of the NMOS transistor T_{N2}), which increases the potential at the node N2, is smaller than the drain current of the NMOS transistor T_{N1}, which decreases the potential at the node N2.

As a result, as shown in FIG. 3, the speed at which the potential at the node N2 increases is slower than the speed at which the potential at the node N2 decreases, which causes the rising delay time t2 to be longer than the falling delay time t1. Accordingly, the falling delay time t4 of the data strobe signal dqsz is longer than the rising delay time t3 of the data strobe signal dqsz. In the same manner, the falling delay time t4 of the data signal dqz is longer than the rising delay time t3 in the second input circuit 2b.

The speed difference between the rising and falling of the data strobe signal dqsz and the data signal dqz in the input circuits 2a, 2b causes the setup time tIS and the hold time tIH of the external data signal DQ, which are shown in FIG. 4, to become unequal to each other. As a result, the latch circuit 3 may latch a data signal DQ having an erroneous level. If the latch circuit 3 provides the internal circuit with an external data signal dinz having an erroneous level, the internal circuit may function abnormally.

Accordingly, it is an objective of the present invention to provide an input circuit that has a uniform delay time of the rising and falling edge of internal signals relative to external signals.

### SUMMARY OF THE INVENTION

To achieve the above objective, the present invention provides an input circuit including a differential circuit which includes a first transistor for receiving an external signal and a second transistor for receiving a reference signal. Sources of the first and second transistors are connected in common and the differential circuit generates an internal signal in accordance with a current flowing through the first and second transistors. A current regulating circuit is connected to the differential circuit. The current regulating circuit regulates the amount of current flowing through the differential circuit in response to the internal signal.

In a further aspect to the present invention, a semiconductor integrated circuit including a plurality of input circuits is provided. Each input circuit includes a differential circuit which includes a first transistor for receiving an external signal and a second transistor for receiving a reference signal. Sources of the first and second transistors are connected in common, and the differential circuit generates an internal signal in accordance with the current flowing through the first and second transistors. A current regulating circuit is connected to the differential circuit, which regulates the amount of current flowing through the differential circuit in response to the internal signal. The integrated circuit further includes a plurality of complementary signal generating circuits, each connected to one of the input circuits. The complementary signal generating circuits receive the internal signal from the associated input circuit and generate a complementary signal of the input signal. A plurality of signal processing circuits are connected to the plurality of complementary signal generating circuits, respectively. The signal processing circuits perform predetermined signal processing operations in accordance with the complementary signal.

In another aspect of the present invention, an input circuit includes a first MOS transistor having a gate that receives a data signal and a second MOS transistor having a gate connected to a reference voltage. The source of the first transistor is connected to the source of the second transistor at a first node. A third MOS transistor is connected between the first node and a low potential power supply, and has its gate connected to a high potential power supply. A fourth MOS transistor is connected between the first node and the low potential power supply. A fifth MOS transistor is connected between the drain of the first transistor and the high potential power supply. A sixth MOS transistor is connected between the drain of the second transistor and the high potential power supply. The gates of the fifth and sixth transistors are connected to each other and to the drain of the sixth transistor. A first inverter has an input terminal connected to a second node between the first and fifth transistors and an output terminal connected to the gate of the fourth transistor.

Other aspects and advantages of the present invention will become apparent from the following description, taken in conjunction with the accompanying drawings, illustrating by way of example the principles of the invention.

### BRIEF DESCRIPTION OF THE DRAWINGS

The invention, together with objects and advantages thereof, may best be understood by reference to the following description of the presently preferred embodiments together with the accompanying drawings in which:

FIG. 1 is a circuit diagram showing a prior art input latch circuit;

FIG. 2 is a circuit diagram showing an input circuit of the input latch circuit of FIG. 2;

FIG. 3 is a timing chart showing the operation of the input circuit of FIG. 2;

FIG. 4 is a timing chart showing the operation of the input latch circuit of FIG. 1;

FIG. 5 is a circuit diagram showing an input latch circuit according to a first embodiment of the present invention;

FIG. 6 is a circuit diagram showing an input circuit of the input latch circuit of FIG. 5;

FIG. 7 is a timing chart showing the operation of the input latch circuit of FIG. 6;

FIG. 8 is a timing chart showing the operation of the input latch circuit of FIG. 5; and

FIG. 9 is a circuit diagram showing an input circuit according to a second embodiment of the present invention.

### DETAILED DESCRIPTION OF THE PREFERRED EMBODIMENTS

In the drawings, like numerals are used for like elements throughout.

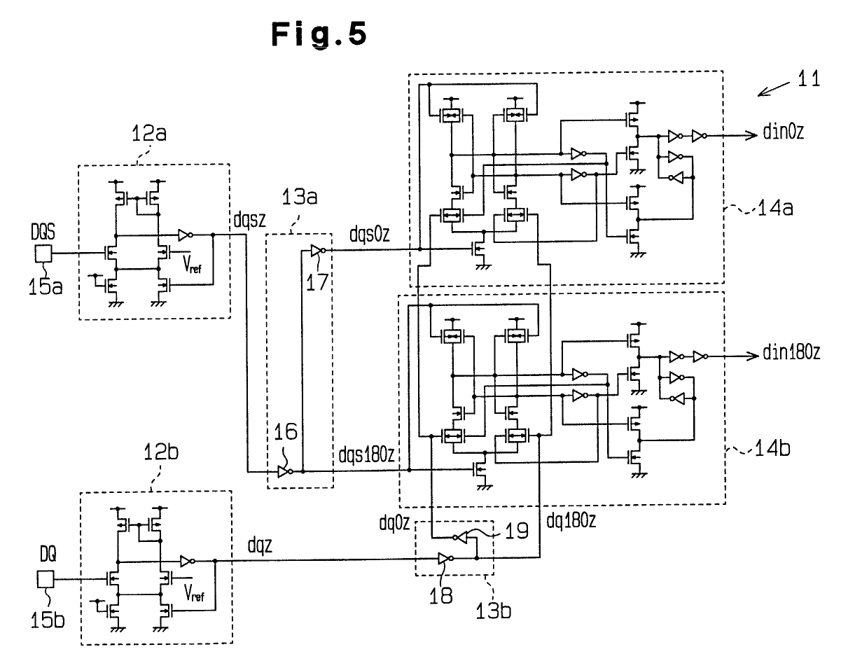

FIG. 5 is a circuit diagram showing an input latch circuit 11 according to a first embodiment of the present invention. The input latch circuit 11 includes a first input circuit 12a, a second input circuit 12b, a first complementary signal generating circuit 13a, a second complementary signal generating circuit 13b, a first latch circuit 14a, and a second latch circuit 14b.

The first input circuit 12a receives an external data strobe signal DQS, which alternates between the V_{IH} and V_{IL} levels, by way of an input pad 15a, amplifies the external data strobe signal DQS, and generates a data strobe signal dqsz, which alternates between the levels of the power supplies V_{CC}, V_{SS} and has a phase that is substantially the same as the external data strobe signal DQS. The data strobe signal dqsz is sent to the first complementary signal generating circuit 13a.

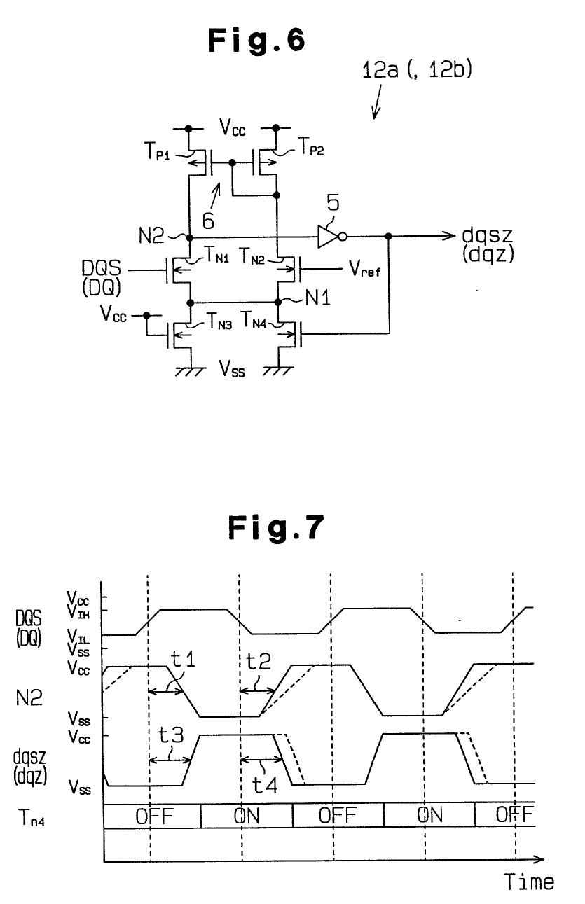

FIG. 6 is a circuit diagram showing the input circuit 12a. The input circuit 12a includes four NMOS transistors T_{N1}-T_{N4}, two PMOS transistors T_{P1}, T_{P2}, and an inverter circuit 5. The NMOS transistors T_{N1}-T_{N3} and the PMOS transistors T_{P1}, T_{P2} form a differential circuit. The NMOS transistor T_{N3} functions as a constant current source.

The drain of the NMOS transistor T_{N4} is connected to a node N1 located between the sources of the NMOS transistors T_{N1}, T_{N2}. The source of the NMOS transistor T_{N4} is connected to a low potential power supply V_{SS}. The gate of the NMOS transistor T_{N4} is connected to the output terminal of an inverter circuit 5. The NMOS transistor T_{N4} goes ON and OFF in response to the data strobe signal dqsz.

The NMOS transistor T_{N4} goes ON when the data strobe signal dqsz is high. As shown in FIG. 7, this period corresponds to the period from when the data strobe signal dqsz rises to the power supply V_{CC} level to when the data strobe signal dqsz falls to the power supply V_{SS} level. When the NMOS transistor T_{N4} is ON, the transistor T_{N4} cooperates with the NMOS transistor T_{N3} and increases the current flowing through the input circuit 12a. Thus, the amount of current is increased in comparison to the prior art input circuit 2a in which only the transistor T_{N3} is used. In other words, the actuation and de-actuation of the NMOS transistor T_{N4} in response to the data strobe signal dqsz regulates the amount of current flowing through the input circuit 12a. Accordingly, the NMOS transistor T_{N4} functions as a current regulating circuit for regulating the amount of current flowing through the input circuit 12a. The period during which the NMOS T_{N4} remains ON corresponds to the period from when the potential at the node N2 goes low to when the potential at the node N2 goes high.

The NMOS transistors T_{N1}, T_{N2} will now be described. As mentioned in the prior art section, the drain current of the NMOS transistor T_{N2} (i.e., the current provided to the node N2 of the current mirror circuit 6 in correspondence with the drain current of the NMOS transistor T_{N2}), which increases the potential at the node N2, is smaller than the drain current of the NMOS transistor T_{N1}, which decreases the potential at the node N2.

The NMOS transistor T_{N4} remains ON in response to the data strobe signal dqsz from when the potential at the node N2 goes low to when the potential goes high. That is, as long as the NMOS transistor T_{N4} remains ON, the NMOS transistor T_{N4} cooperates with the NMOS transistor T_{N3} and increases the amount of current flowing through the input circuit 12a. In this state, the amount of current flowing through the NMOS transistor T_{N2} (i.e., the amount of current provided to the node N2 by the current mirror circuit 6) is substantially the same as the amount of drain current flowing through the NMOS transistor T_{N1}.

Accordingly, the NMOS transistor T_{N4} increases the current drive capability when the NMOS transistor T_{N2} is actuated so that the current drive capability is substantially the same as that when the NMOS transistor T_{N1} is ON. That is, the NMOS transistor T_{N4} causes the speed at which the potential at the node N2 varies to be substantially the same as the speed at which the drain potential at the NMOS transistor T_{N1} varies.

As a result, as shown in FIG. 7, the speed at which the potential at the node N2 increases is substantially the same as the speed at which the potential at the node N2 decreases. This results in the rising delay time t2 to be substantially the same as the falling delay time t1. Accordingly, the falling delay time t4 and the rising delay time t3 of the data strobe signal dqsz output by the input circuit 12a are substantially the same.

As shown in FIG. 5, the second input circuit 12b receives an external data signal DQ, which alternates between the V_{IH} and V_{IL} levels, by way of an input pad 15b, amplifies the external data signal DQ, and generates a data signal dqz, which alternates between the levels of the power supplies V_{CC}, V_{SS} and has a phase that is substantially the same as the external data strobe signal DQ. The structure of the second input circuit 12b is substantially the same as that of the first input circuit 12a. Thus, the falling delay time t4 and the rising delay time t3 of the data signal dqz provided to the second complementary signal generating circuit 13b from the second input circuit 12b are substantially the same.

The first complementary signal generating circuit 13a receives the data strobe signal dqsz from the input circuit 12a and generates a normal phase data strobe signal dqs0z and an inverted phase data signal dqs180z. The second complementary signal generating circuit 13b receives the data signal dqz from the input circuit 12b and generates a normal phase data signal dq0z and an inverted phase data signal dq180z. The latch circuits 14a, 14b respectively generate a normal phase internal data signal din0z and an inverted phase internal data signal din180z based on the normal and inverted phase data strobe signals dqs0z, dqs180z and the normal and inverted phase data signals dq0z, dq180z.

The first complementary signal generating circuit 13a includes two inverter circuits 16, 17, which are connected to each other in series. The first inverter circuit 16 has an input terminal which receives the data strobe signal dqsz from the first input circuit 12a and an output terminal for providing the inverted phase data strobe signal dqs180z to the second latch circuit 14b. The second inverter circuit 17 has an input terminal that receives the inverted phase data strobe signal dqs180z from the first inverter circuit 16 and an output terminal for providing the normal phase data strobe signal dqs0z to the first latch circuit 14a.

The second complementary signal generating circuit 13b includes two inverter circuits 18, 19, which are connected to each other in series. The first inverter circuit 18 has an input terminal which receives the data signal dqz from the second input circuit 12b and an output terminal for providing the inverted phase data signal dq180z to the first and second latch circuits 14a, 14b. The second inverter circuit 19 has an input terminal that receives the inverted phase data signal dq180z from the first inverter circuit 18 and an output terminal for providing the normal phase data signal dq0z to the first and second latch circuits 14a, 14b.

The inverter circuits 16-19 of the first and second complementary signal generating circuits 13a, 13b are preferably CMOS inverter circuits. The operation speed (response speed) of each of the NMOS and PMOS transistors of the inverter circuits 16-19 can be represented as Pch (16), Nch (16), Pch (17), Nch (17), Pch (18), Nch (18), Pch (19), Nch (19). In this case, the response rate of each MOS transistor is set based on equation (1).

$$\frac{Pch ( 16 )}{Nch ( 16 )} < \frac{Pch ( 18 )}{Nch ( 18 )} = \frac{Pch ( 19 )}{Nch ( 19 )} < \frac{Pch ( 17 )}{Nch ( 17 )} \qquad ( 1 )$$

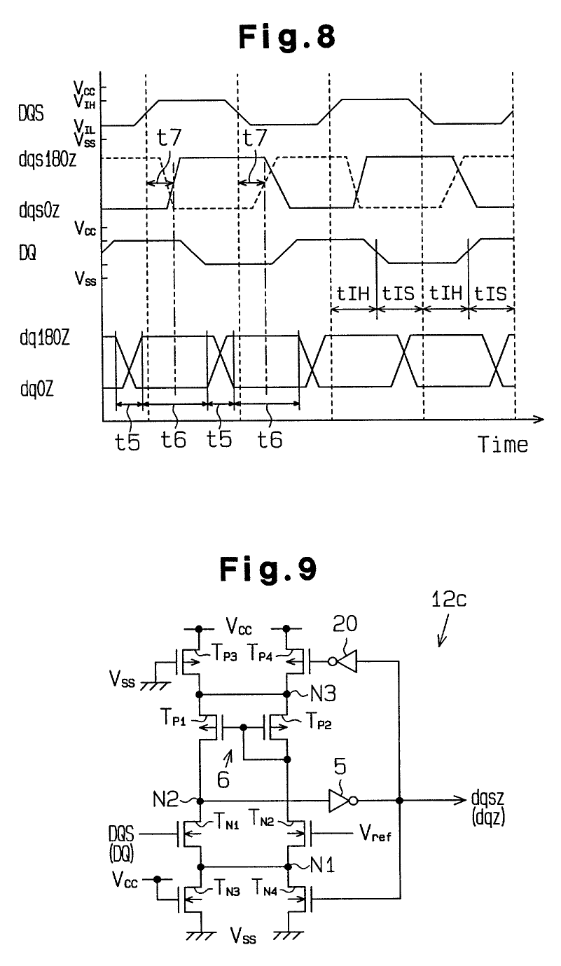

In other words, the MOS transistor response rate of the inverter circuit 18 is substantially equal to that of the inverter circuit 19. By setting the response rate in this manner, each of the indeterminate times t5, during which the level of the data signals dq0z, dq180z change, becomes equal to one another as shown in FIG. 8.

The MOS transistor response rate of the inverter circuit 16 is less than that of the inverter circuits 18, 19. The MOS transistor response rate of the inverter circuit 17 is greater than that of the inverter circuits 18, 19. That is, the response speed Nch(16) is set so that it is faster than the response speed Pch(16) in the inverter circuit 16. Furthermore, the response speed Pch(17) is set so that it is faster than the response speed Nch(17) in the inverter circuit 17.

By setting the response rate in this manner, the falling time of the signal output from the inverter circuit 16 and the rising time of the signal output from the inverter circuit 17 decrease, while the falling time of the signal output from the inverter circuit 17 increases. As a result, as shown in FIG. 8, the rising delay times t7 of the data strobe signals dqs0z, dqs180z are substantially equal to one another.

Furthermore, as shown in FIG. 8, the MOS transistor response rate of the inverter circuits 16-19 is set such that the data strobe signals dqs0z, dqs180z go substantially high at the halfway point of each determinate time t6. The determinate time t6 refers to the time excluding the indeterminate time t5 of the data signals dq0z, dq180z.

The first latch circuit 14a latches a high data signal dq0z or a high data signal dq180z (i.e., low data signal dq0z) in response to the rising edge of the normal phase data strobe signal dqs0z. The latch circuit 14a outputs the latched data signal as the normal phase internal data signal din0z.

The second latch circuit 14b latches a high data signal dq0z or a high data signal dq180z (i.e., low data signal dq0z) in response to the rising edge of the inverted phase data strobe signal dqs180z. The latch circuit 14b outputs the latched data signal as the inverted phase internal data signal din180z.

With reference to FIG. 8, the input latch circuit 11 acquires and latches the external data signal DQ in response to the rising and falling edges of the external data strobe signal DQS and holds the latched signal until the subsequent edge of the external data strobe signal DQS. The input latch circuit 11 outputs the normal phase internal data signal din0z of the external data strobe signal DQS and the inverted phase internal data signal din180z of the external data strobe signal DQS. The normal phase internal data signal din0z is the data signal latched in response to the rising edge of the external data strobe signal DQS. The inverted phase internal data signal din180z is the data signal latched in response to the falling edge of the external data strobe signal DQS.

The input latch circuit 11 is, for example, incorporated in a double data rate (DDR)-SDRAM. The operation of the DDR-SDRAM is based on the external data signal DQ, which is acquired in accordance with the rising and falling edges of the external data strobe signal DQS.

The input latch circuit 11 improves the waveforms of the data strobe signal dqsz, the data signal dqz, the data strobe signals dqs0z, dqs180z, and the data signal dq0z, dq180z such that the edge of the external data strobe signal DQS is located at intermediate positions of the external data signal DQ. In other words, the waveform of each signal is improved such that the setup time tIS and the hold time tIH of the external data signal DQ are substantially the same. This increases the operating margin of the DDR-SRAM and permits the DDR-SDRAM to operate stably at high speeds.

The characteristics of the first embodiment will now be described.

(1) The input circuits 12a, 12b are each provided with the NMOS transistor T_{N3} and the NMOS transistor T_{N4}, which are connected in parallel, between the node N1 and the low potential power supply V_{SS}. The gate of the NMOS transistor T_{N4} is provided with the data strobe signal dqsz (data signal dqz). The NMOS transistor T_{N4} remains actuated as long as the data strobe signal dqsz (data signal dqz) is high. More specifically, as shown in FIG. 7, the NMOS transistor T_{N4} is actuated from when the data strobe signal dqsz (data signal dqz) rises to the power supply V_{CC} level to when the signal dqsz (dqz) falls to the power supply V_{SS} level. The actuated NMOS transistor T_{N4} cooperates with the NMOS transistor T_{N3} to increase the amount of current flowing through the input circuit 12a (12b). The current amount is greater in comparison to when employing only the transistor T_{N3}.

In other words, the actuation and de-actuation of the NMOS transistor T_{N4} in response to the data strobe signal dqsz (data signal dqz) regulates the amount of current flowing through the input circuit 12a. The amount of current flowing through the NMOS transistor T_{N2} (i.e., the amount of current provided to the node N2 by the current mirror circuit 6) is substantially the same as the amount of drain current flowing through the NMOS transistor T_{N1}. Thus, as shown in FIG. 7, the speed at which the potential at the node N2 increases becomes higher and causes the potential increasing speed to become substantially the same as the speed at which the potential at the node N2 decreases. As a result, the rising delay time t2 and the falling delay time t1 are substantially the same. This results in the rising delay time t2 and the falling delay time t1 being substantially the same. Accordingly, the falling delay time t4 and the rising delay time t3 of the data strobe signal dqsz output by the input circuit 12a are substantially the same. This improves the delay time of the signal output from the input circuit 12a.

(2) The structure of each input circuit 12a, 12b is relatively simple.

(3) The NMOS transistor T_{N4} is actuated and de-actuated in response to the data strobe signal (data signal dqz). This simplifies the structure of the input circuit 12a (12b).

(4) The first and second complementary signal generating circuits 13a, 13b each include two inverter circuits. This makes the operation delay time of the first and second complementary signal generating circuits 13a, 13b substantially uniform. As a result, the processing speed of the latch circuits 14a, 14b increases and the operating margin of the latch circuits is improved.

(5) The response rate of each MOS transistor in the inverter circuits 18, 19 is substantially the same. Furthermore, as shown in FIG. 8, each indeterminate time t5, during which the levels of the data signal dq0z, dq180z change, is substantially the same. Accordingly, the substantially uniform indeterminate time t5 of the data signals dq0z, dq180z increases the processing speed of the latch circuits 14a, 14b and improves their operation margin.

(6) The inverter circuit 16 is designed so that the response speed Nch(16) is higher than the response speed Pch(16), and the inverter circuit 17 is designed so that the response speed Pch(17) is higher than the response speed Nch(17). This increases the falling speed of the signal output from the inverter circuit 16 and decreases the rising speed of the signal output from the inverter circuit 17. As a result, as shown in FIG. 8, each rising delay time t7 of the data strobe signals dqs0z, dqs180z is substantially the same. Accordingly, the processing speed of the latch circuits 14a, 14b increases and their operation margin improves.

FIG. 9 is a circuit diagram showing an input circuit 12c according to a second embodiment of the present invention. The sources of the PMOS transistors T_{P1}, T_{P2} in the current mirror circuit 6 are connected to each other at the connection node N3 and are further connected to the high potential power supply V_{CC} by way of PMOS transistors T_{P3}, T_{P4}, which are connected in parallel to each other. The gate of the PMOS transistor T_{P3} is connected to a low potential power supply V_{SS}. Thus, the PMOS transistor T_{P3} functions as a constant current source. The data strobe signal dqsz (data signal dqz) is provided to the gate of the PMOS transistor T_{P4} by way of an inverter circuit 20. Accordingly, the PMOS transistor T_{P4} and the NMOS transistor T_{N4} are actuated and de-actuated at substantially the same timing.

In the second embodiment, the PMOS transistor T_{P4} and the NMOS transistor T_{N4} are both held in an actuated state from when the potential at the node N2 goes low to when the potential goes substantially high. That is, during this period, the NMOS transistor T_{N4} and the PMOS transistor T_{P4} cooperate with the NMOS transistor T_{N3} and increases the amount of current flowing through the input circuit 12c. Accordingly, in the second embodiment, a current regulating circuit is formed by the NMOS transistor T_{N4}, the PMOS transistor T_{P4}, and the inverter circuit 20. The current regulating circuit causes the amount of current flowing through the NMOS transistor T_{N2} (i.e., the amount of current provided to the node N2 by the current mirror circuit 6) to be substantially the same as the amount of drain current flowing through the NMOS transistor T_{N1}. As a result, as shown in FIG. 7, the potential rising speed at the node N2 increases and becomes substantially the same as the potential falling speed causing the operation delay time t2 to be substantially the same as the operation delay time t1. In this manner, the input circuit 12c outputs a data strobe signal dqsz (data signal dqz) having substantially the same falling delay time t4 and rising delay time t3.

In the second embodiment, the NMOS transistor T_{N4} may be eliminated. In this case, the PMOS transistors T_{P3}, T_{P4} and the inverter circuit 20 form a current regulating circuit. Furthermore, the current regulating circuit may be formed from appropriate circuits and elements other than the NMOS transistor T_{N4}, the PMOS transistors T_{P3}, T_{P4}, and the inverter circuit 20.

It should be apparent to those skilled in the art that the present invention may be embodied in many other specific forms without departing from the spirit or scope of the invention. Particularly, it should be understood that the present invention may be embodied in the following forms.

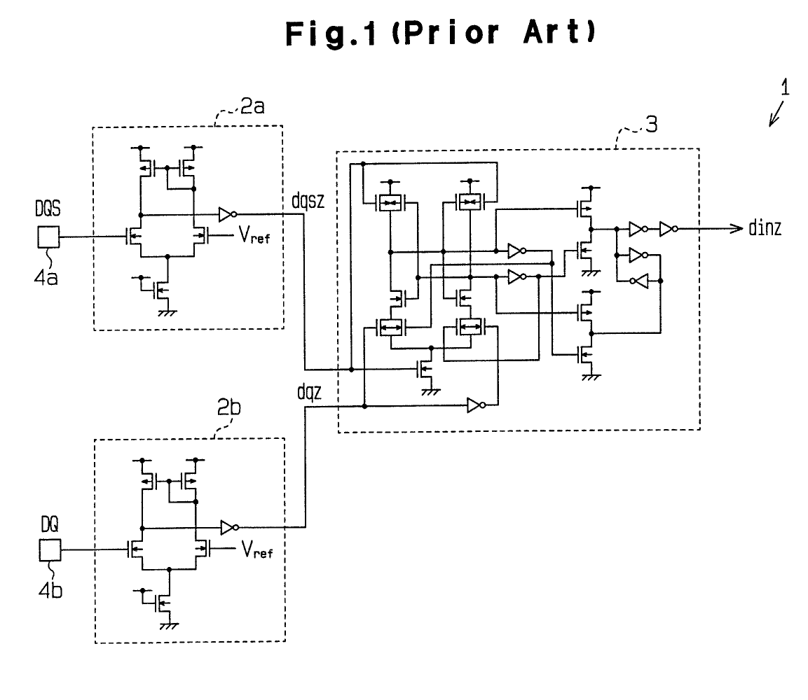

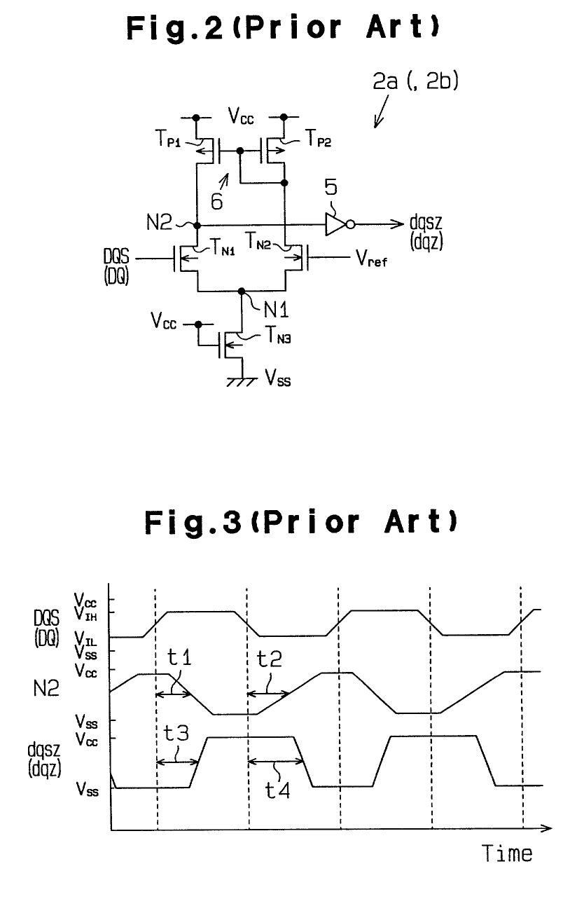

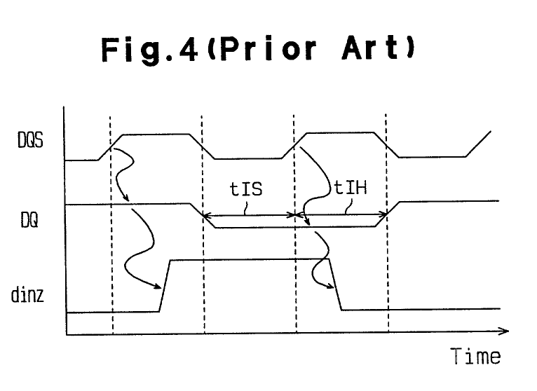

The input latch circuit 11 according to the present invention may be applied to an SDRAM. In this case, the first and second latch circuits 14a, 14b are replaced by the latch circuit 3 of FIG. 1 which generates the internal data signal dinz.

The differential circuit of the input circuits 12a, 12b need not be formed by the current mirror circuit 6 and the constant current source (NMOS transistor T_{N3}).

The present examples and embodiments are to be considered as illustrative and not restrictive, and the invention is not to be limited to the details given herein, but may be modified within the scope and equivalence of the appended claims.

What is claimed is:

1. An input circuit comprising:
a differential circuit including a first transistor for receiving an external signal and a second transistor for receiving a reference signal, wherein sources of the first and second transistors are connected in common, and the differential circuit generates an internal signal in accordance with a current flowing through the first and second transistors; and
a current regulating circuit connected to the differential circuit, wherein the current regulating circuit regulates the amount of current flowing through the differential circuit in response to the internal signal.

2. The input circuit according to claim 1, wherein the external signal has a first transition point and a second transition point, wherein the internal signal has a third transition point and a fourth transition point corresponding to the first transit point and the second transit point, respectively, and wherein the current regulating circuit regulates the amount of current flowing through the differential circuit such that a delay time between the first transition point and the third transition point is substantially the same as the delay time between the second and fourth transition points.

3. The input circuit according to claim 1, wherein the differential circuit includes a constant current source, and wherein the current regulating circuit is connected in parallel to the constant current source.

4. The input circuit according to claim 3, wherein the constant current source is connected to a high potential power supply, and wherein the current regulating circuit includes a transistor connected in parallel to the constant current source, the transistor going ON and OFF in response to the internal signal.

5. The input circuit according to claim 3, wherein the constant current source is connected to a low potential power supply, and wherein the current regulating circuit includes a transistor connected in parallel to the constant current source, the transistor going ON and OFF in response to the internal signal.

6. A semiconductor integrated circuit comprising:
a plurality of input circuits, each input circuit including:
a differential circuit including a first transistor for receiving an external signal and a second transistor for receiving a reference signal, wherein sources of the first and second transistors are connected in common, and the differential circuit generates an internal signal in accordance with the current flowing through the first and second transistors; and
a current regulating circuit, connected to the differential circuit, which regulates the amount of current flowing through the differential circuit in response to the internal signal;
a plurality of complementary signal generating circuits, each connected to one of the input circuits, wherein the complementary signal generating circuits receive the internal signal from the associated input circuit and generate a complementary signal of the input signal; and
a plurality of signal processing circuits connected to the plurality of complementary signal generating circuits, respectively, wherein the signal processing circuits perform predetermined signal processing operations in accordance with the complementary signal.

7. The integrated circuit according to claim 6, wherein each complementary signal generating circuit includes a plurality of inverter circuits.

8. The integrated circuit according to claim 7, wherein each complementary signal generating circuit includes the same number of the inverter circuits.

9. The integrated circuit according to claim 7, wherein the complementary signal has a transition period, and wherein each inverter circuit includes a pair of MOS transistors having a response rate set such that the transition period of the generated complementary signal is constant.

10. The integrated circuit according to claim 7, wherein the complementary signals each having a rising edge, include a normal phase signal and an inverted phase signal, and wherein each inverter circuit includes a pair of MOS transistors having a response rate set such that the delay time from an edge of the external signal to the rising edge of the normal phase signal and a delay time from an edge of the external signal to the rising edge of the inverted phase signal is substantially the same.

11. The integrated circuit according to claim 6, wherein the plurality of input circuits includes:
a first input circuit for receiving an external strobe signal and generating a strobe signal; and
a second input circuit for receiving an external data signal and generating a data signal;
wherein the plurality of complementary signal generating circuits includes:
a first complementary signal generating circuit for receiving the strobe signal and generating a normal phase strobe signal and an inverted phase strobe signal; and
a second complementary signal generating circuit for receiving the data signal and generating a normal phase data signal and an inverted phase data signal; and
wherein the plurality of signal processing circuits includes:
a first latch circuit for latching the normal phase data signal from the second complementary signal generating circuit in accordance with the normal phase strobe signal from the first complementary signal generating circuit; and
a second latch circuit for latching the inverted phase data signal from the second complementary signal generating circuit in accordance with the inverted phase strobe signal from the first complementary signal generating circuit.

12. The integrated circuit according to claim 6, wherein the external signal has a first transition point and a second transition point, wherein the internal signal has a third transition point and a fourth transition point corresponding to the first transition point and the second transition point, respectively, and wherein the current regulating circuit regulates the amount of current flowing through the differential circuit such that a delay time between the first transition point and the third transition point is substantially the same as the delay time between the second and fourth transition points.

13. The input circuit according to claim 12, wherein the differential circuit includes a constant current source connected in parallel to the current regulating circuit.

14. The input circuit according to claim 13, wherein the constant current source is connected to a high potential power supply, and wherein the current regulating circuit includes a transistor connected in parallel to the constant current source, the transistor going ON and OFF in response to the internal signal.

15. The input circuit according to claim 13, wherein the constant current source is connected to a low potential power supply, and wherein the current regulating circuit includes a transistor connected in parallel to the constant current source, the transistor going ON and OFF in response to the internal signal.

16. An input circuit comprising:
a first MOS transistor having a gate that receives a data signal;
a second MOS transistor having a gate connected to a reference voltage, wherein the source of the first transistor is connected to the source of the second transistor at a first node;
a third MOS transistor connected between the first node and a low potential power supply, and having its gate connected to a high potential power supply;
a fourth MOS transistor connected between the first node and the low potential power supply;
a fifth MOS transistor connected between the drain of the first transistor and the high potential power supply;
a sixth MOS transistor connected between the drain of the second transistor and the high potential power supply, wherein the gates of the fifth and sixth transistors are connected to each other and to the drain of the sixth transistor; and
a first inverter having an input terminal connected to a second node between the first and fifth transistors and an output terminal connected to the gate of the fourth transistor.

17. The input circuit of claim 16, wherein the first, second, third and fourth transistors are NMOS transistors.

18. The input circuit of claim 17, wherein the fifth and sixth transistors are PMOS transistors.

19. The input circuit of claim 16, further comprising:
a latch circuit connected to the output terminal of the first inverter.

20. The input circuit of claim 16, further comprising:
a seventh transistor, connected between the fifth transistor and the high potential power supply, having a gate connected to the low potential power supply;
an eighth transistor connected between the sixth transistor and the high potential power supply, wherein the sources of the fifth and sixth transistors are connected to each other at a third node; and
a second inverter having an input terminal connected to the output terminal of the first inverter and an output terminal connected to the gate of the eighth transistor.
